(19) United States
(12) Patent Application Publication
(10) Pub. No.: US 2024/0379271 A1
(43) Pub. Date: Nov. 14, 2024

(54) METHOD AND SYSTEM FOR OPERATING AN ON-LOAD TAP CHANGER, AND ON-LOAD TAP CHANGER COMPRISING SUCH A SYSTEM

(71) Applicant: Maschinenfabrik Reinhausen GmbH, Regensburg (DE)

(72) Inventors: Sebastian Rehkopf, Regensburg (DE); Michael Heger, Straubing (DE); Markus Klein, Regensburg (DE); Roman Kagerer, Regensburg (DE); Guenter Panzer, Regensburg (DE); Sebastian Daiser, Regenstauf (DE)

(21) Appl. No.: 18/580,727

(22) PCT Filed: Jun. 27, 2022
(86) PCT No.: PCT/EP2022/067542

§ 371 Date: Jan. 19, 2024

(30) Foreign Application Priority Data
Jul. 22, 2021 (DE) 10 2021 119 006.1

(51) Int. Cl. H01F 21/12

(52) U.S. Cl. CPC H01F 21/12

(57) ABSTRACT

An on-load tap changer for a tapped transformer has a controller configured to actuate the on-load tap changer; and a storage unit. A method of operating the tap changer includes: carrying out a switching operation of the on-load tap changer by the controller; updating at least one data record stored in the storage unit depending on the switching operation carried out; checking on a basis of the updated data record whether a locking condition is met, by the controller; and blocking further switching operations based on determining that the locking condition is met, by the controller.

### CROSS REFERENCE TO RELATED APPLICATIONS

This application is a U.S. National Phase application under 35 U.S.C. § 371 of International Application No. PCT/EP2022/067542, filed on Jun. 27, 2022, and claims benefit to German Patent Application No. DE 10 2021 119 006.1, filed on Jul. 22, 2021. The International Application was published in German on Jan. 26, 2023 as WO 2023/001496 A1 under PCT Article 21 (2).

### FIELD

The present disclosure relates to a method and a system for operating an on-load tap changer, and to an on-load tap changer comprising the system.

### BACKGROUND

On-load tap changers are used for uninterruptibly switching between winding taps of a transformer and are accordingly essential equipment for transformers where particular attention is paid to the reliability thereof. In order to ensure trouble-free and reliable operation of the on-load tap changer, regular inspections and possibly maintenance and service work need to be performed on the on-load tap changer, which are associated with a degree of planning and control expenditure, in particular on the part of the transformer operator.

One significant parameter for the lifetime of an on-load tap changer is, for example, the number of switching operations carried out, in view of the mechanical wear of the components of the on-load tap changer that are subjected to loading during switching. If an on-load tap changer continues to be operated despite inspection being due or possibly maintenance or service work being due, the risk of damage to the on-load tap changer or even complete failure increases.

### SUMMARY

In an embodiment, the present disclosure provides an on-load tap changer for a tapped transformer that has a controller configured to actuate the on-load tap changer; and a storage unit. A method of operating the tap changer includes: carrying out a switching operation of the on-load tap changer by the controller; updating at least one data record stored in the storage unit depending on the switching operation carried out; checking on a basis of the updated data record whether a locking condition is met, by the controller; and blocking further switching operations based on determining that the locking condition is met, by the controller.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows one advantageous embodiment of a system in accordance with the improved concept in a schematic illustration;

FIG. 2 shows one advantageous embodiment of the method in accordance with the improved concept; and

FIG. 3 shows a further advantageous embodiment of the method in accordance with the improved concept.

### DETAILED DESCRIPTION

Aspects of the present disclosure provide an improved concept for operating an on-load tap changer, which allows efficient and simplified monitoring of the on-load tap changer with regard to inspections and maintenance or service work due, and thus, ensures reliable and trouble-free operation of the transformer together with the on-load tap changer.

In accordance with a first aspect of the improved concept, a method is provided. A method for operating an on-load tap changer for transformers is provided, wherein the on-load tap changer has a control unit for actuating the on-load tap changer and a storage unit. Moreover, the method comprises the following steps: In the first step, a switching operation of the on-load tap changer is carried out by the control unit. For this purpose, the on-load tap changer preferably has a motor drive actuated by the control unit. In the next step, at least one data record stored in the storage unit is updated depending on the switching operation carried out. In the next step in turn, the control unit checks on the basis of the updated data record whether a locking condition is met. In the next step, further switching operations are blocked by the control unit if the locking condition is met.

The blocking of further switching operations if the locking condition is met automatically prevents ongoing actuation of the on-load tap changer. Presence of trained service personnel on site for checking whether a locking condition is met is therefore not necessary.

A data record stored in the storage unit is a data record which changes with the number of switching operations carried out, such as, for example, the number of tap-change operations, i.e. the number of switching operations carried out, and/or the level of the cumulated quantity of charge or the quantity of transferred energy.

A locking condition is met, e.g., if a defined number of tap-change operations, i.e. a defined number of switching operations carried out overall, and/or a defined number of switching operations carried out in a defined period of time, and/or a defined level of cumulated quantity of charge or a defined quantity of transferred energy are/is reached and/or exceeded.

It is likewise possible for the period of time within which the on-load tap changer has been operated since installation, and/or the period of time that has elapsed since the last inspection performed and/or since the last maintenance or service work performed, to be used as a stored data record for the comparison with the locking condition. Accordingly, the locking condition is met if a defined period of operation since start-up and/or since the last inspection, maintenance or repair of the on-load tap changer is reached and/or exceeded.

In accordance with one advantageous embodiment of the method, the method comprises the following further steps: In a further step, the locking condition is updated by the control unit. In a succeeding step, the control unit checks on the basis of the updated data record whether the updated locking condition is met. If the updated locking condition is not met, at least one further switching operation is carried out by the control unit. In particular, a plurality of further switching operations are allowed by the control unit as long as the updated locking condition is not met. If the checking of the updated data record reveals that the updated locking condition is met, further switching operations are blocked by the control unit.

The updating of the locking condition alters the condition for blocking further switching operations. If the number of tap-change operations is used as a data record under consideration, then the value for the number of switching operations carried out at which further switching operations are intended to be blocked is changed, in particular set higher. If the level of the cumulated quantity of charge or the quantity of transferred energy as a data record is compared with the locking condition, then in the context of updating the locking condition the value for the maximum permissible cumulated quantity of charge which is permitted to be switched, or the maximum permissible quantity of energy which is permitted to be transferred, is adapted and in particular set higher or greater before the blocking of further switching operations occurs.

If the period of time that has elapsed since start-up or the last maintenance is considered as a data record, in the context of updating the locking condition the time recording is restarted or the defined period of operation within which further switching operations are allowed is changed, in particular extended.

The locking condition can be updated at least once. Repeated updates of the locking condition are likewise possible until a maximum locking condition is reached. That means that an updated locking condition can also represent a maximum locking condition.

In accordance with one advantageous embodiment of the method, updating the locking condition comprises the following steps: In a first step, an unlocking condition is communicated to the control unit. In a next step, the control unit verifies whether the unlocking condition is valid. If the unlocking condition is valid, updating the locking condition is effected in the next step.

In accordance with one advantageous embodiment of the method, verifying whether the unlocking condition is valid comprises the following steps: By the control unit, at least one first release code is compared with at least one second code stored beforehand in the storage unit. In this case, the unlocking condition is met if the first release code is verified by way of the second code.

Verifying the first release code by way of the second code means specifically that the first release code and the second code match and/or the first release code supplements the second code and/or the second code supplements the first release code.

In accordance with one embodiment, the second code is generated by an algorithm that is executed on the basis of features of the control, such as the serial number or the production date, for example.

In accordance with a further embodiment, the release code and the second code are generated on the basis of blockchain technology.

In accordance with a further embodiment, the control unit has an input unit configured to read external storage media and/or to detect manual inputs. For the input of data into the control unit, the input unit can be configured in any desired way. By way of example, the input unit can be configured as a local operating unit on the control unit and can have a rotary wheel arranged on the control unit, keys, a connection for external storage media, for example a connection for a USB stick or an SD card, or a touchscreen or combinations thereof. Likewise, the input unit can be configured as a mobile terminal, for example a tablet or smartphone, and can be wirelessly connectable to the control unit.

The release code is communicated to the control unit by the input unit via a manual input or a data file. The data file can be communicated to the control unit for example from a USB stick connected to the input unit.

The control unit and the input unit can be configured in each case as separate units or as a common structural unit.

In accordance with a further embodiment, the control unit has a communication unit configured to communicate data to a superordinate control and/or monitoring system and to receive data from the superordinate control and/or monitoring system.

In accordance with one embodiment, the release code is communicated from the superordinate control and/or monitoring system to the control unit by the communication unit.

The data transfer between the communication unit and the superordinate control and/or monitoring system is effected wirelessly and can be realized in any desired manner. By way of example, the data transfer is effected via Bluetooth, WLAN, LAN, WAN or radio.

The communication unit is connectable to the superordinate control and/or monitoring system permanently and/or at defined time intervals and/or manually triggerably via the input unit.

A superordinate control and/or monitoring system is the control center, for example.

A superordinate control and/or monitoring system is for example a web-based and/or cloud-based portal configured for receiving, transmitting and evaluating data.

The control unit and the communication unit can be configured in each case as separate units or as a common structural unit.

In accordance with one embodiment, the control unit has an input unit configured to output a status message of the on-load tap changer representing the state of the on-load tap changer and of the control unit.

In accordance with one embodiment, the method comprises the following further step: outputting a status message representing the state of the on-load tap changer and of the control unit, by the output unit.

For outputting the status message, the output unit has for example corresponding status-signalling LED illuminants and/or a screen.

By way of example, the following states of the on-load tap changer and of the controller may occur: ready for operation, locking condition not met, sufficient interval before occurrence of the locking condition, ready for operation (warning), locking condition not met, insufficient interval before occurrence of the locking condition, blocked, locking condition met, no more switching operations possible, etc.

The control unit and the output unit can be configured in each case as separate units or as a common structural unit.

In accordance with one embodiment, the input unit and the output unit are configured as separate units or as a common unit.

In accordance with a further embodiment, the method comprises the following further steps: If the locking condition and/or the updated locking condition are/is not met, the control unit checks on the basis of the updated data record whether a warning condition is met. If the warning condition is met, a warning message is output by the output unit, and/or a warning message is communicated to the superordinate control and/or monitoring system by the communication unit.

For outputting the warning message, the output unit has for example corresponding status-signaling LED illuminants and/or a screen.

A warning condition may be met if a defined number of tap-change operations, i.e. a defined number of switching operations carried out overall, and/or a defined number of switching operations carried out in a defined period of time, and/or a defined level of cumulated quantity of charge or a defined quantity of transferred energy are/is reached and/or exceeded.

A warning condition may likewise be met if a defined period of operation since start-up and/or since the last maintenance or repair of the on-load tap changer has elapsed and/or is exceeded.

A warning condition can correspond to a locking condition and/or an updated locking condition.

A warning condition can deviate from a locking condition and/or an updated locking condition.

By way of example, the value for the defined number of tap-change operations, i.e. the defined number of switching operations carried out overall, and/or the defined number of switching operations carried out in a defined period of time, and/or the defined level of cumulated quantity of charge or the defined quantity of transferred energy at which the warning condition is met can be defined as lower or smaller in comparison with a locking condition and/or an updated locking condition.

By way of example, the defined period of operation since start-up and/or since the last inspection, maintenance or repair of the on-load tap changer for meeting a warning condition can be fixed as shorter in comparison with a locking condition and/or an updated locking condition.

In accordance with one embodiment, the method comprises the following further steps: state data representing the state of the on-load tap changer and/or of the control unit and/or of the transformer are captured by suitable sensors and the control unit. In a next step, these state data are stored in the storage unit and optionally evaluated by the control unit.

For the evaluation, the control unit can have corresponding assessment logic facilities and/or assessment algorithms that are stored in the storage unit.

Likewise, the state data can be exported and/or communicated by the communication unit to the superordinate control and/or monitoring system and there they can be evaluated by means of corresponding assessment logic facilities and/or assessment algorithms and/or can be output by the output unit.

The outputting of the state types by the output unit primarily serves for the retrieval of state data of the on-load tap changer and/or of the control unit on site. The output unit has for this purpose suitable means for visualizing the state data, for example a screen.

In accordance with a further embodiment, updating the locking condition is effected depending on the process of exporting and/or communicating the state data. In particular, the process of exporting and/or communicating the state data can be an unlocking condition.

The following data are captured as state data and saved, for example: number of tap-change operations, system voltage, load current, operating time, torque, torque profile, tap position, switching time, number of positions or winding taps moved to, and residence time, motor temperature, internal temperature of the on-load tap changer or of the control cabinet.

Any desired sensors that are correspondingly suitable for the respective purpose of use can be used for capturing the state data. By way of example, the following sensors are suitable for capturing the data mentioned: measuring transducers, temperature sensors, angle sensors or acceleration sensors.

In accordance with a second aspect of the improved concept, a system is provided.

The features of the system correspond to the steps of the method in accordance with the first aspect of the present disclosure. For the system in accordance with the second aspect of the present disclosure, reference is therefore analogously made to the advantageous explanations, preferred features, technical effects and/or advantages that have already been explained for the method in accordance with the first aspect of the present disclosure. There is therefore no repetition.

With respect to the advantageous configurations of the system that are presented below, reference is also analogously made to the explanations, features, method steps, technical effects and advantages that have already been explained for the corresponding embodiments of the method. Here too, there is no similar repetition.

A system for operating an on-load tap changer for transformers is provided, the system comprising a storage unit and a control unit for controlling the on-load tap changer. The control unit is configured to carry out a method in accordance with the first aspect of the present disclosure. The control unit preferably controls a motor drive that in turn actuates the on-load tap changer.

In accordance with one embodiment, the control unit and the motor drive form a common structural unit.

The storage unit can be configured as a separate unit as part of the on-load tap changer or as a common unit with the control unit or as part of the control unit.

In accordance with one embodiment, the system furthermore comprises a communication unit configured to communicate data to a superordinate control and/or monitoring system and to receive data from the superordinate control and/or monitoring system, wherein the first release code is communicated from the superordinate control and monitoring system to the control unit by the communication unit.

In accordance with a further embodiment, the control unit has an input unit configured to read external storage media and/or to detect manual user inputs, wherein the first release code is communicated to the control unit by the input unit.

In accordance with a further embodiment, the control unit has an output unit configured to output a status message of the on-load tap changer representing the state of the on-load tap changer.

The input unit and the output unit can be configured in each case as separate units or as a common unit.

In accordance with a further embodiment, the second code is generated by an algorithm and/or is generated on the basis of blockchain technology.

In accordance with a third aspect of the improved concept, an on-load tap changer comprising a system in accordance with the second aspect is specified.

The present disclosure is explained below in detail on the basis of exemplary embodiments with reference to the drawings. Components which are identical or functionally identical or which have an identical effect may be provided with identical reference signs. Identical components or components with an identical function are in some cases explained only in relation to the figure in which they first appear. The explanation is not necessarily repeated in the subsequent figures.

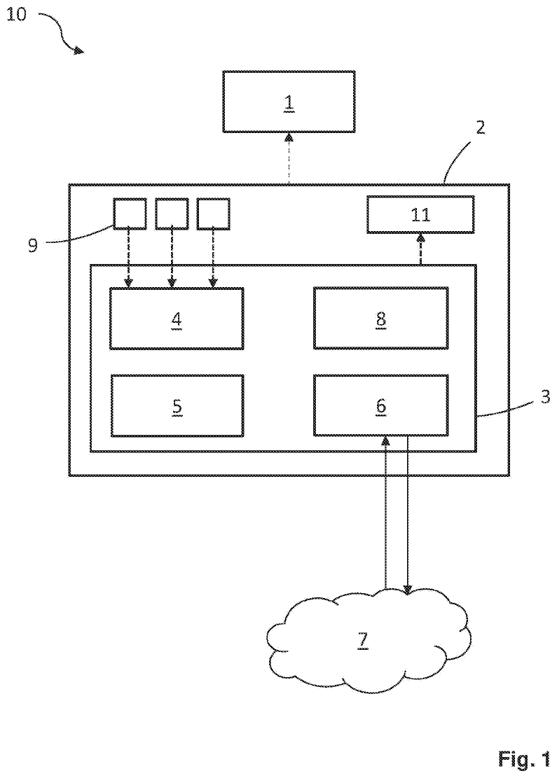

FIG. 1 shows one advantageous embodiment of a system 10 in accordance with the improved concept in a schematic illustration. The system 10 has an on-load tap changer 2 for uninterruptibly switching between winding taps of a tap-changing transformer 1. The on-load tap changer 2 comprises a control unit (also referred to herein as a controller) 3 and a motor drive 11, which is actuated by the control unit 3 for the purpose of carrying out a switching operation of the on-load tap changer 2. The on-load tap changer 2 furthermore comprises a storage unit 4, an input unit 5, an output unit 8 and a communication unit 6. In accordance with the advantageous embodiment shown in FIG. 1, these units 4, 5, 6 and 8 are in each case part of the control unit 3 or configured as a common unit with the control unit 3. It is likewise possible, however, for the units 4, 5, 6 and 8 to be configured in each case as an independent unit, i.e. in a manner spatially separated from the control unit 3.

The storage unit 4 is configured for storing data records. By way of example, in the storage unit 4 data are stored which change with the number of switching operations carried out, such as e.g. the number of tap-change operations or the level of the cumulated quantity of charge or the quantity of transferred energy. Further data that can be stored in the storage unit 4 are state data concerning the on-load tap changer 2, such as, for example, the system voltage, the load current, the operating time, the torque, the torque profile, the tap position, switching times, the number of positions or winding taps moved to, and the respective residence time in a position, the motor temperature, the internal temperature of the on-load tap changer or of the control cabinet, or other data concerning the on-load tap changer 2. These state data are captured by suitable sensors 9, optionally evaluated by the control unit 3 and stored in the storage unit 4.

Furthermore, at least one second code serving for verifying a release code for releasing further switching operations for the on-load tap changer 2 is stored in the storage unit 4. The release code can for example be input manually via the input unit 5, or be transferred to the storage unit 4 via the input unit 5 by an external storage medium in the form of a data file.

Moreover, the release code can be communicated from a superordinate control and/or monitoring system 7, for example the control center or a data portal of the network operator, to the control unit 3 via the communication unit 6. The communication unit 6 is configured in return to communicate warning messages, state data or other data concerning the on-load tap changer 2 to the superordinate control and/or monitoring system 7.

By the output unit 8, status messages concerning the state of the on-load tap changer 2 are output, such as, for example, the state data captured by the sensors 9 and optionally evaluated by the control unit 3. Moreover, warning messages, blocking messages or other messages concerning the state of the on-load tap changer 2 can be output on site via the output unit 8.

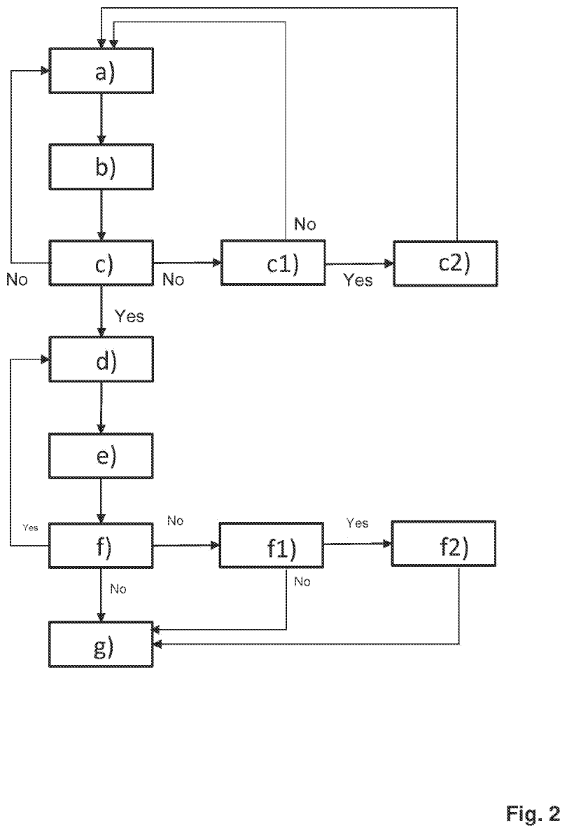

FIG. 2 illustrates one advantageous embodiment of the method in accordance with the improved concept in the form of a flowchart. In accordance with this advantageous embodiment, the on-load tap changer 2 comprises a control unit 3 for carrying out the method, comprising the following steps: In a step a, by the control unit 3, the motor drive 11 is actuated and a switching operation of the on-load tap changer 2 is carried out. Afterward, in a step b, at least one data record stored in the storage unit 4, preferably the number of tap-change operations, is updated. In a step c, the control unit 3 checks on the basis of the updated data record, i.e. on the basis of the updated number of tap-change operations, whether a locking condition is met. In accordance with this advantageous embodiment, the locking condition is met if a defined number of tap-change operations of the on-load tap changer 2 has been exceeded. If the locking condition is met, i.e. if the updated number of tap-change operations is higher than the defined number of tap-change operations, then with step d further switching operations of the on-load tap changer 2 are blocked by the control unit 3. In particular, the motor drive 11 is blocked by the control unit 3. If the locking condition is not met, i.e. the updated number of tap-change operations is less than or equal to the defined number of tap-change operations, then upon the next switching command the method can begin again at step a.

However, if further switching operations have been blocked, in step e the locking condition is updated by the control unit 3. That means, specifically, that the locking condition is altered, i.e. e.g. the defined number of tap-change operations as of which blocking is to be effected is increased. Afterward, in step f, by the control unit 3, on the basis of the updated data record, i.e. on the basis of the number of tap-change operations updated after the switching operation, a check is made to ascertain whether the updated locking condition, i.e. the increased number of tap-change operations, has been exceeded. If this is not the case, i.e. the updated number of tap-change operations is less than or equal to the increased number of tap-change operations and the updated locking condition is therefore not met, then step g involves carrying out at least one further switching operation by the control unit 3. Step g can be repeated in particular until the updated locking condition is met, i.e. the updated number of tap-change operations is higher than the increased number of tap-change operations. If this is the case, the method recommences at step d and further switching operations are blocked by the control unit 3. The loop of steps d to f can preferably be repeated until a maximum locking condition is attained. The on-load tap changer 2 has then reached its maximum number of tap-change operations, for example.

After steps c and f, in accordance with this advantageous embodiment, for the case where the locking condition (step c) and respectively the updated locking condition (step f) have not been met, steps c1 and respectively f1 are additionally carried out. Accordingly, on the basis of the updated data record, a check is made to ascertain whether a warning condition, for example a specific number of tap-change operations being exceeded, is met. If the warning condition is met, in step c2 and respectively f2, a warning message is output by the output unit 8, and/or a warning message is communicated to the superordinate control and/or monitoring system 7 by the communication unit 6. After steps c2 and respectively f2 or even if the warning condition is not met, i.e. a specific number of tap-change operations has not yet been reached, the method is restarted at step a, and respectively continued at step g.

With regard to the method, reference is analogously made to the previous explanations, preferred features, effects and/or advantages that have already been explained for the system 1 with reference to FIG. 1. There is therefore no corresponding repetition.

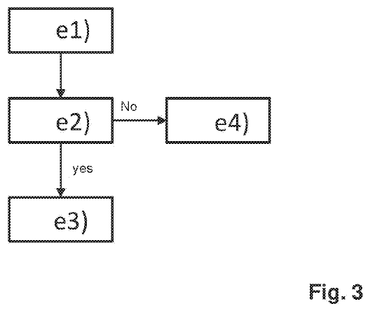

FIG. 3 illustrates a further advantageous embodiment of the method in accordance with the improved concept in the form of a flowchart. Accordingly, updating the locking condition in accordance with step e comprises sub-steps e1 to e3. In step e1, an unlocking condition is communicated to the control unit 3. In a step e2, the control unit 3 verifies whether the unlocking condition is valid. In this case, at least one first release code is compared with at least one second code stored beforehand in the storage unit 4, by the control unit 3. If the first release code is verified by way of the second code already stored, e.g. by way of a match, then the unlocking condition is met. In this case, in step e3, the locking condition is updated, i.e. e.g. the number of tap-change operations at which further switching operations of the on-load tap changer 2 are blocked is increased. However, if the unlocking condition is not valid, which is the case e.g. if the first release code is not verified by way of the second code, then the locking condition is not updated. That means that the on-load tap changer remains blocked. In this case, with step e4, an error message is output via the output unit 8 and/or a corresponding message is communicated to the superordinate control and/or monitoring system via the communication unit 6. This case may occur for example if the on-load tap changer 2 has reached its maximum number of tap-change operations.

With regard to this advantageous embodiment of the method, too, reference is analogously made to the previous explanations, preferred features, effects and/or advantages that have already been explained for the system 1 with reference to FIG. 1. There is therefore no corresponding repetition.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C

### REFERENCE SIGNS

1 Tap-changing transformer
2 On-load tap changer
3 Control unit
4 Storage unit
5 Input unit
6 Communication unit
7 Control and/or monitoring system
8 Output unit
9 Sensor
10 System
11 Motor

1. A method for operating an on-load tap changer for a tapped transformer, the on-load tap changer comprising a controller configured to actuate the on-load tap changer; and a storage unit, the method comprising:
carrying out a switching operation of the on-load tap changer by the controller;
updating at least one data record stored in the storage unit depending on the switching operation carried out;
checking on a basis of the updated data record whether a locking condition is met, by the controller; and
blocking further switching operations based on determining that the locking condition is met, by the controller.

2. The method as claimed in claim 1, wherein the method further comprises:
updating the locking condition by the controller;
checking on the basis of the updated data record whether the updated locking condition is met, by the controller, and
either:
carrying out at least one further switching operation based on determining that the updated locking condition is not met, by the controller, or
blocking further switching operations based on determining that the updated locking condition is met, by the controller.

3. The method as claimed in claim 2, wherein updating the locking condition comprises:
communicating an unlocking condition to the controller;
verifying whether the unlocking condition is valid, by the controller; and
updating the locking condition based on determining that the unlocking condition is valid.

4. The method as claimed in claim 3, wherein verifying whether the unlocking condition is valid comprises:
comparing at least one first release code with at least one second code stored beforehand in the storage unit, by the controller,
wherein the unlocking condition is determined as met based on determining that the first release code is verified by way of the second code.

5. The method as claimed in claim 4, wherein the second code is generated by an algorithm or is generated on the basis of blockchain technology.

6. The method as claimed in claim 4, wherein
the controller has an input unit configured to read external storage media or to detect manual inputs, and
the method further comprises communicating the release code to the controller by the input unit via a manual input or a data file.

7. The method as claimed in claim 4, wherein
the controller comprises a communication unit configured to communicate data to a superordinate control or monitoring system and to receive data from the superordinate control or monitoring system,
the method further comprises communicating the release code from the superordinate control or monitoring system to the controller, by the communication unit.

8. The method as claimed in claim 1, wherein;
the controller comprises an output unit configured to output a status message of the on-load tap changer, and
the method further comprises outputting a status message representing the state of the on-load tap changer.

9. The method as claimed in claim 1, wherein the method further comprises:
checking on the basis of the updated data record whether a warning condition is met based on determining that the locking condition or the updated locking condition is not met; and:
outputting a warning message by the output unit based on determining that the warning condition is met, or
communicating a warning message to the superordinate control or monitoring system by the communication unit based on determining that the warning condition is met.

10. The method as claimed in claim 1, wherein the method further comprises:
capturing state data by sensors and the controller;
storing the state data in the storage unit; and:
exporting or communicating the state data to the superordinate control or monitoring system, or
outputting the state data by the output unit.

11. The method as claimed in claim 10, wherein updating the locking condition is effected depending on the process of exporting or communicating the state data.

12. A system for operating an on-load tap changer for a tapped transformer, the system comprising:
a storage unit; and
a controller configured to control the on-load tap changer,
wherein the controller is configured to carry out the method as claimed in claim 1.

13. The system as claimed in claim 12, furthermore comprising:
a communication unit configured to communicate data to a superordinate control or monitoring system and to receive data from the superordinate control or monitoring system,
wherein a first release code is communicated from the superordinate control or monitoring system to the controller, by the communication unit.

14. The system as claimed in claim 12,
wherein the controller comprises an input unit configured to read external storage media or to detect manual user inputs, and
wherein first release code is communicated to the controller by the input unit.

15. The system as claimed in claim 12, wherein the controller comprises an output unit configured to output a status message of the on-load tap changer representing the state of the on-load tap changer.

16. The system as claimed in claim 12, wherein;
the second code is generated by an algorithm, or
the second code is generated on the basis of blockchain technology.

17. An on-load tap changer for a tapped transformer comprising the system configured as claimed in claim 12.
